(19) United States
(12) Patent Application Publication
(10) Pub. No.: US 2026/0262166 A1
(43) Pub. Date: Sep. 3, 2026

(54) ELECTRONIC EQUIPMENT

(71) Applicant: CANON KABUSHIKI KAISHA, Tokyo (JP)

(72) Inventors: HIROYUKI YAMAGUCHI, Kanagawa (JP); TAKAYUKI TAGUCHI, Kanagawa (JP)

(21) Appl. No.: 19/547,982

(22) Filed: Feb. 24, 2026

(30) Foreign Application Priority Data
Feb. 28, 2025 (JP) 2025-032060

(51) Int. Cl. H05K 1/14; H05K 1/181; H05K 1/189; H10F 39/00

(52) U.S. Cl. CPC H05K 1/147; H05K 1/181; H05K 1/189; H05K 2201/058; H05K 2201/10287; H10F 39/811

(57) ABSTRACT

An electronic equipment includes a semiconductor element including a first circuit and a second circuit, a wiring board on which the semiconductor element is mounted, a flexible wiring unit connected to the wiring board, a power unit connected to the flexible wiring unit, and a plurality of conductive members connecting the wiring board and the semiconductor element. The electronic equipment is configured to supply power from the power unit to the first circuit via the flexible wiring unit, a first power wiring provided on the wiring board, and at least four conductive members of the plurality of conductive members, and to supply power from the power unit to the second circuit via the flexible wiring unit, a second power wiring provided on the wiring board, and at least one conductive member of the plurality of conductive members.

### BACKGROUND

### Field of the Technology

The present disclosure relates to an electronic equipment.

### Description of the Related Art

In an electronic equipment, power is supplied to a semiconductor element using a plurality of conductive members that connects a wiring board and the semiconductor element. Japanese Patent Laid-Open No. 2023-53806 discloses an electronic equipment including a plurality of connection wirings that connects a power source wiring and an imaging device each other, at least two power supply sources connected to the power source wiring, and at least one power supply source connected to the power supply wiring. A fifth embodiment of Japanese Patent Laid-Open No. 2023-53806 discloses an imaging element unit in which a wiring portion for supplying power to a left end side of an imaging substrate and a wiring portion for supplying power to a right end side of the imaging substrate are routed from a connector (power supply connection portion).

In a case where there are a plurality of systems of power to be supplied to the semiconductor element, the potential fluctuation of the power wiring of one system may propagate to the power wiring of the other system to affect the operation of the semiconductor element.

### SUMMARY

The present disclosure is directed to provide an electronic equipment that operates well.

According to one aspect of the present disclosure, there is provided an electronic equipment including a semiconductor element including a first circuit and a second circuit, a wiring board on which the semiconductor element is mounted, a flexible wiring unit connected to the wiring board, a power unit connected to the flexible wiring unit, and a plurality of conductive members connecting the wiring board and the semiconductor element. The electronic equipment is configured to supply power from the power unit to the first circuit via the flexible wiring unit, a first power wiring provided on the wiring board, and at least four conductive members of the plurality of conductive members, and to supply power from the power unit to the second circuit via the flexible wiring unit, a second power wiring provided on the wiring board, and at least one conductive member of the plurality of conductive members. The four conductive members include a first conductive member, a second conductive member, a third conductive member, and a fourth conductive member. A first connection portion among a plurality of connection portions connecting the flexible wiring unit and the wiring board is disposed on a wiring path connecting the first conductive member and the second conductive member in the first power wiring. A second connection portion among the plurality of connection portions connecting the flexible wiring unit and the wiring board is disposed on a wiring path connecting the third conductive member and the fourth conductive member in the first power wiring.

Features of the present disclosure will become apparent from the following description of embodiments with reference to the attached drawings. The following description of embodiments is described by way of example.

### BRIEF DESCRIPTION OF THE DRAWINGS

FIG. 1 is a schematic cross-sectional view of an electronic equipment according to a first embodiment.

FIG. 2 is a block diagram of the electronic equipment according to the first embodiment.

FIG. 3 is a diagram illustrating wirings connected to a pixel according to the first embodiment.

FIG. 4 is a perspective view of the wiring board according to the first embodiment.

FIG. 5 is a bottom view of the wiring board, the connection portion, and the flexible wiring unit according to the first embodiment.

FIG. 6 is a cross-sectional view of the wiring board according to the first embodiment.

FIG. 7 is a plan view of the wiring layer according to the first embodiment.

FIG. 8 is a plan view of the wiring layer according to the first embodiment.

FIG. 9 is a schematic diagram illustrating a current of the digital power wiring pattern according to the first embodiment.

FIG. 10 is a schematic diagram illustrating a current of the digital power wiring pattern according to a modified example.

FIG. 11 is a plan view of a wiring layer according to a second embodiment.

FIG. 12 is a plan view of a wiring layer according to a third embodiment.

FIG. 13 is a plan view of a wiring layer according to a fourth embodiment.

FIG. 14 is a plan view of a wiring layer according to a fifth embodiment.

FIG. 15 is a plan view of a wiring layer according to a sixth embodiment.

FIG. 16 is a plan view of a wiring layer according to a seventh embodiment.

FIG. 17 is a plan view of a wiring layer according to the seventh embodiment.

### DESCRIPTION OF THE EMBODIMENTS

### First Embodiment

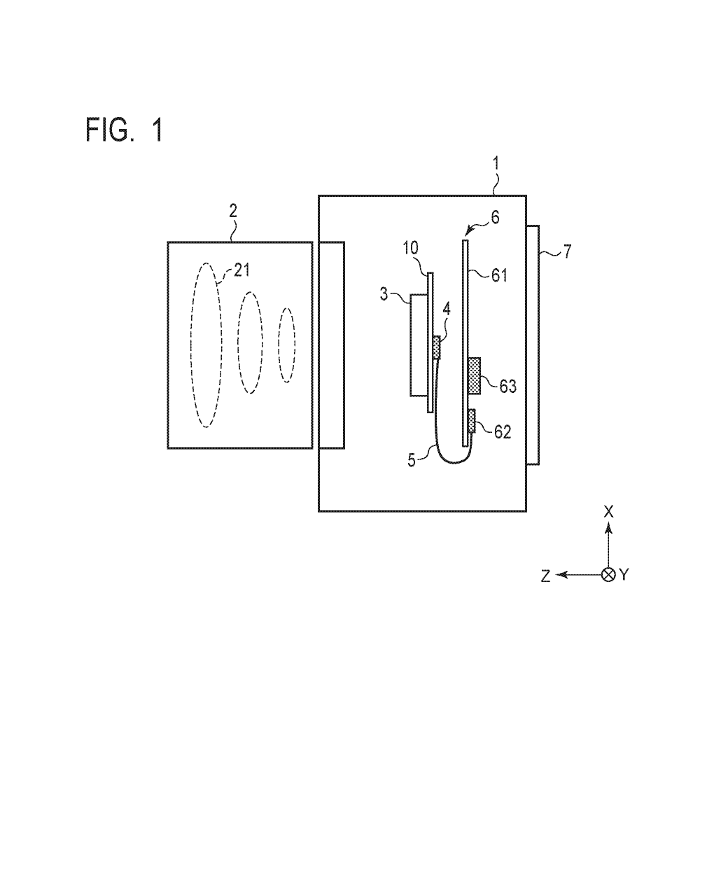

FIG. 1 is a schematic cross-sectional view of an electronic equipment according to the present embodiment. The electronic equipment according to the present embodiment is a digital camera such as a digital still camera or a digital video camera. Although FIG. 1 illustrates a digital single-lens camera with an interchangeable lens as an example of the electronic equipment according to the present embodiment, the present disclosure is not limited thereto. For example, the electronic equipment may be an information terminal with a camera such as a smartphone or a personal computer. Here, the Z axis is an imaging direction of the electronic device, and the X axis and the Y axis are two different directions orthogonal to the Z axis.

The electronic equipment includes a camera body 1, a lens unit 2, a semiconductor element 3, a connection portion 4, a flexible wiring unit 5, a processing module 6, a display 7, and a wiring board 10.

The lens unit 2 is attached to the camera body 1. The lens unit 2 may be detachable from the camera body 1, and the lens unit 2 may be configured integrally with the camera body 1. The lens unit 2 includes lenses 21. Although three lenses 21 are illustrated in FIG. 1, the number of lenses 21 is not limited thereto.

Inside the camera body 1, the semiconductor element 3, the connection portion 4, the flexible wiring unit 5, the processing module 6, and the wiring board 10 are provided.

The semiconductor element 3 is mounted on the wiring board 10. The semiconductor element 3 is, for example, an imaging element. The semiconductor element 3 may be configured by a CMOS (Complementary Metal Oxide Semiconductor) image sensor, a CCD (Charge Coupled Device) image sensor, a SPAD (Single Photon Avalanche Diode) image sensor, or the like. The semiconductor element 3 converts an optical image formed by the lenses 21 into an electrical signal by photoelectric conversion, and outputs an image signal. Note that, the semiconductor element 3 is not limited to the imaging element. The semiconductor element 3 may be a display element, an acoustic element, or other sensor elements.

The wiring board 10 is, for example, a printed wiring board. The wiring board 10 is provided with a connection portion 4. The flexible wiring unit 5 is, for example, a flexible printed wiring board or a flexible flat cable. One end of the flexible wiring unit 5 is connected to the connection portion 4, and the other end of the flexible wiring unit 5 is connected to the connection portion 62. The flexible wiring unit 5 is provided with wirings for inputting and/or outputting signals between the wiring board 10 and the processing module 6.

The processing module 6 includes a wiring board 61, a connection portion 62, and an image processing unit 63. The wiring board 61 is, for example, a printed wiring board. The wiring board 61 is provided with a connection portion 62. The image processing unit 63 is mounted on the wiring board 61, and the image processing unit 63 may be a digital signal processor that processes the image signal output from the semiconductor element 3. The image processing unit 63 may be an integrated circuit configured by a semiconductor package.

The image signal from the semiconductor element 3 is input to the image processing unit 63 via the wiring board 10, the connection portion 4, the flexible wiring unit 5, and the connection portion 62. The image processing unit 63 performs image processing such as noise reduction, demosaicing, and color balance on the image signal, and outputs image data.

The display 7 is attached to the camera body 1. The display 7 is configured by a liquid crystal panel, an organic light emitting panel, or the like, and is a display device that displays an image based on image data of the image processing unit 63.

The camera body 1 may be provided with a storage device for storing an output signal from the semiconductor element 3. The storage device may be configured by, for example, a semiconductor memory such as a DRAM (Dynamic Random Access Memory), and an SRAM(Static Random Access Memory).

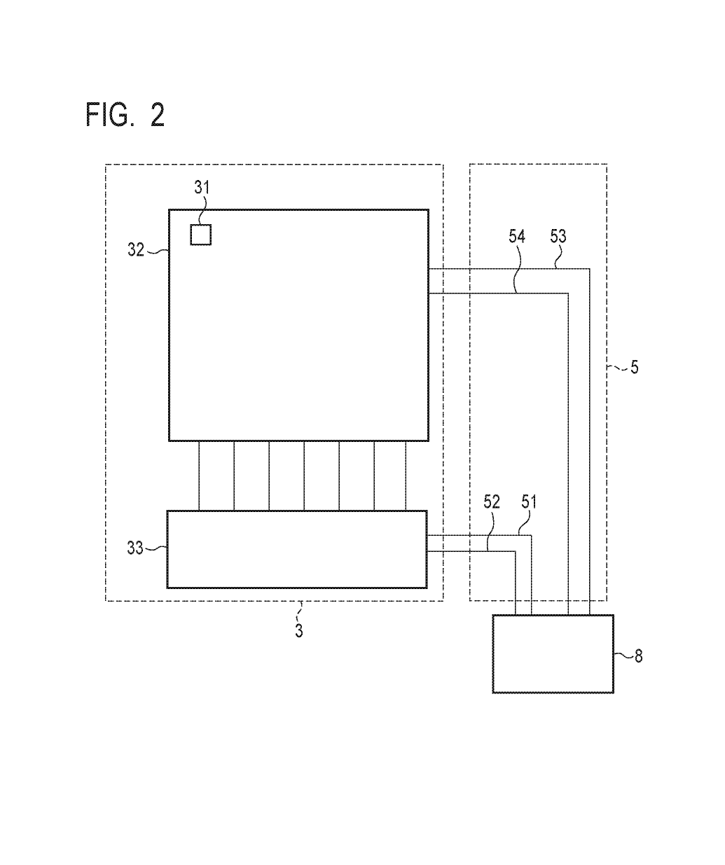

FIG. 2 is a block diagram of the electronic equipment according to the present embodiment. The electronic equipment includes the semiconductor element 3, the flexible wiring unit 5, and a power unit 8. The semiconductor element 3 includes a pixel 31, an analog circuit 32, and a digital circuit 33. The digital circuit 33 is an example of a first circuit, and the analog circuit 32 is an example of a second circuit.

The analog circuit 32 of the semiconductor element 3 includes a plurality of pixels 31 arranged in a matrix. The pixel 31 includes a photodiode, a floating diffusion capacitor, a transfer transistor, and the like. The analog circuit 32 may further include a readout circuit, a clock generation circuit, and a bias generation circuit. The analog circuit 32 processes a continuously varying charge or voltage and may include an amplifier circuit, a filter circuit, and the like. The digital circuit 33 of the semiconductor element 3 includes an A/D conversion circuit, a digital control circuit, an ISP (Image Signal Processor), a data buffering circuit, a communication circuit, and the like.

The power unit 8 is mounted on, for example, an external substrate (not illustrated), and may include a DC-DC converter, a regulator circuit, and the like. The power unit 8 generates power for driving the analog circuit 32 and the digital circuit 33 of the semiconductor element 3 via the flexible wiring unit 5. In FIG. 2, the power unit 8 is provided in common to the analog circuit 32 and the digital circuit 33, but different power units 8 may be provided to the analog circuit 32 and the digital circuit 33, respectively. The power unit 8 may be configured by a single element or a plurality of elements.

The flexible wiring unit 5 includes a digital power wiring 51, a ground wiring 52, an analog power wiring 53, and a ground wiring 54. The digital power wiring 51 and the ground wiring 52 are connected to the digital circuit 33. A power from the power unit 8 to the digital circuit 33 is supplied to the digital power wiring 51. A return current from the digital circuit 33 flows through the ground wiring 52. The analog power wiring 53 and the ground wiring 54 are connected to the analog circuit 32. A power from the power unit 8 to the analog circuit 32 is supplied to the analog power wiring 53. A return current from the analog circuit 32 flows through the ground wiring 54. Although the digital power wiring 51 and the analog power wiring 53 are provided with individual ground wirings 52 and 54, respectively, the present disclosure is not limited thereto. A common ground wiring may be provided for the digital power wiring 51 and the analog power wiring 53. Although not illustrated, the flexible wiring unit 5 may include signal wiring for transmitting an image signal, a control signal, and the like.

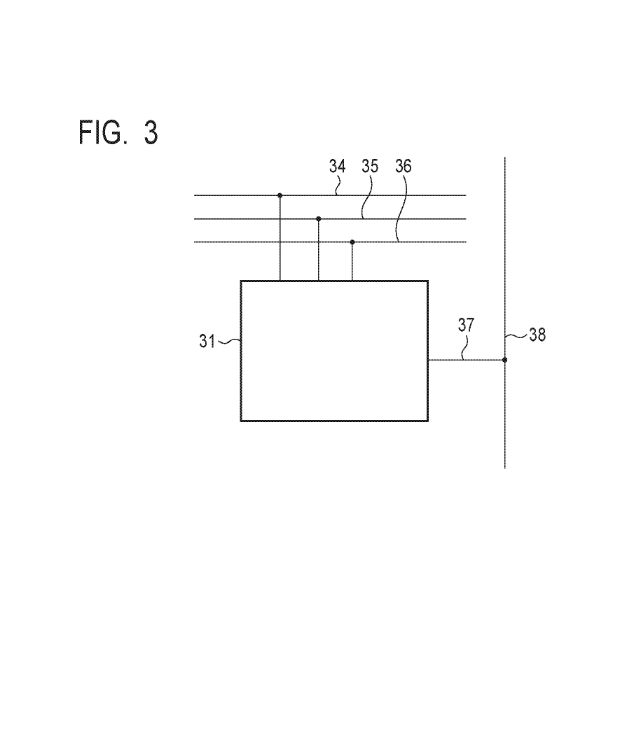

FIG. 3 is a diagram illustrating wirings connected to the pixel 31. An analog power wiring 34, a ground wiring 35, a control wiring 36, and a signal wiring 37 are connected to the pixel 31. Note that the wirings connected to the pixel 31 are not limited to those in FIG. 3. For example, a reset wiring (not illustrated) is connected to the pixel 31.

The analog power wiring 34 supplies power from the analog power wiring 53 to the pixel 31, and the ground wiring 35 returns return current from the pixel 31 to the ground wiring 54. The control wiring 36 supplies a control signal for row readout and row selection, a reset signal for resetting accumulated charges, and the like to the pixels 31 from a scanning circuit (not illustrated). An optical image is formed on the pixel 31 by the lenses 21. The pixel 31 generates a pixel signal by photoelectric conversion, and outputs the pixel signal to a column signal wiring 38 via the signal wiring 37. Further, the pixel signal is output to the digital circuit 33 via the column signal wiring 38. The digital circuit 33 converts the pixel signal into a digital image signal and outputs the image signal to the image processing unit 63.

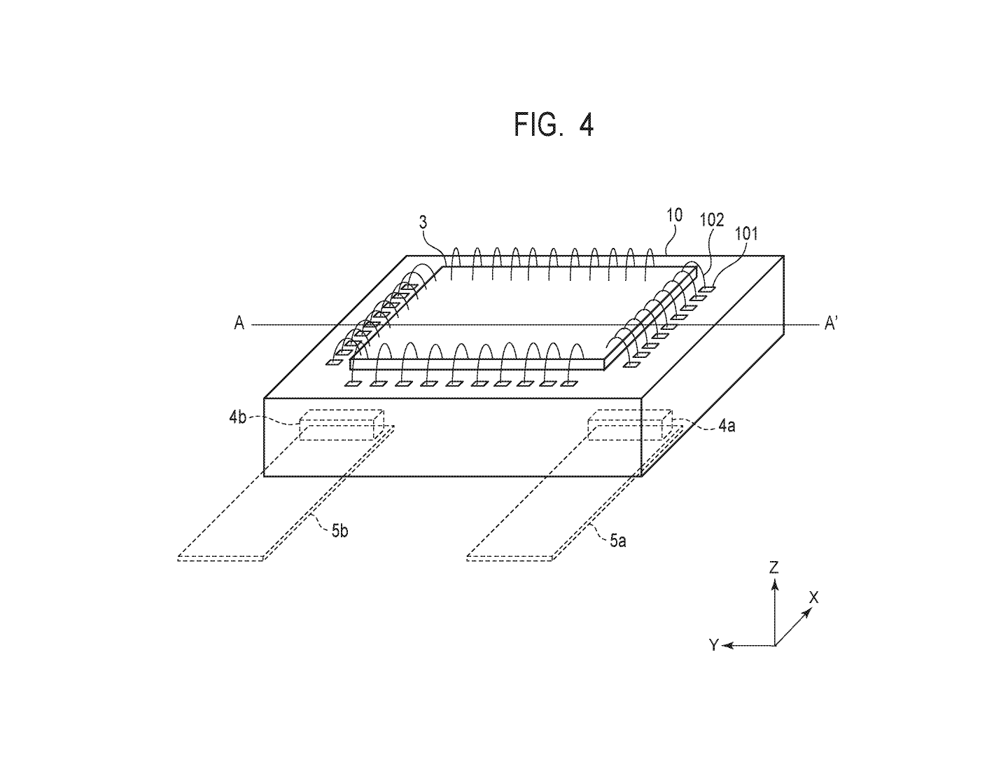

FIG. 4 is a perspective view of the wiring board 10 according to the present embodiment. The wiring board 10 is formed of a plate-like hexahedron and has a quadrilateral shape in a plan view in the Z direction. The semiconductor element 3 is mounted on the upper surface of the wiring board 10. The semiconductor element 3 is formed of a plate-like hexahedron and has a quadrilateral shape in a plan view in the Z direction, similarly to the wiring board 10. Of the six surfaces of the hexahedron of the semiconductor element 3, the largest surface is referred to as the main surface of the semiconductor element 3. The main surface of the semiconductor element 3 may be an interface between the functional surface of the semiconductor element 3 and the insulator. For example, when the semiconductor element 3 is a CMOS sensor, the main surface of the semiconductor element 3 may be a light incident surface from the insulator to the semiconductor or an interface between the oxide film of the MOS (Metal Oxide Semiconductor) transistor and the semiconductor.

On the upper surface of the wiring board 10, a plurality of pads 101 are provided around the semiconductor element 3. Each of the plurality of pads 101 is connected to the semiconductor element 3 via a bonding wire (conductive member) 102. The plurality of pads 101 is connected to the analog circuit 32 and the digital circuit 33. The plurality of pads 101 may be provided so as to be dispersed along the outer periphery of the semiconductor element 3. For example, in the plurality of pixels 31, the difference in the length of the wiring from the pad 101 to the pixel 31 of the semiconductor element 3 becomes small, and the fluctuation in the power supplied to the pixel 31 of the semiconductor element 3 can be reduced. Similarly, in the plurality of digital circuits 33, the difference in wiring length from the pad 101 to the digital circuit 33 can be reduced.

The connection portions 4a and 4b are connected to the lower surface of the wiring board 10. One end of the flexible wiring unit 5a is connected to the connection portion 4a, and the other end of the flexible wiring unit 5a is connected to the connection portion 62. One end of the flexible wiring unit 5b is connected to the connection portion 4b, and the other end of the flexible wiring unit 5b is connected to the connection portion 62.

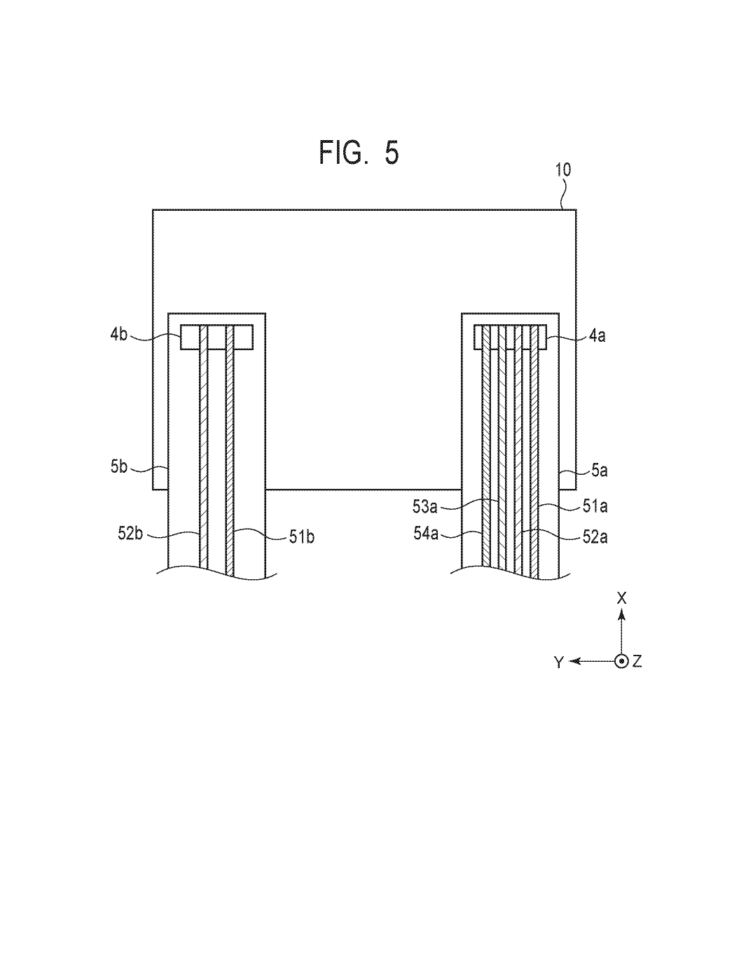

FIG. 5 is a bottom view of the wiring board 10, the connection portions 4a and 4b, and the flexible wiring units 5a and 5b according to the present embodiment. The connection portion 4a is provided on the right side portion of the lower surface of the wiring board 10, and the connection portion 4b is provided on the left side portion of the lower surface of the wiring board 10. The flexible wiring unit 5a is provided with a digital power wiring 51a, a ground wiring 52a, an analog power wiring 53a, and a ground wiring 54a. The flexible wiring unit 5b is provided with a digital power wiring 51b and a ground wiring 52b.

In a plan view of the flexible wiring unit 5a, the digital power wiring 51a is provided side by side with the ground wiring 52a, and the analog power wiring 53a is provided side by side with the ground wiring 54a. In a plan view of the flexible wiring unit 5b, the digital power wiring 51b is provided side by side with the ground wiring 52b.

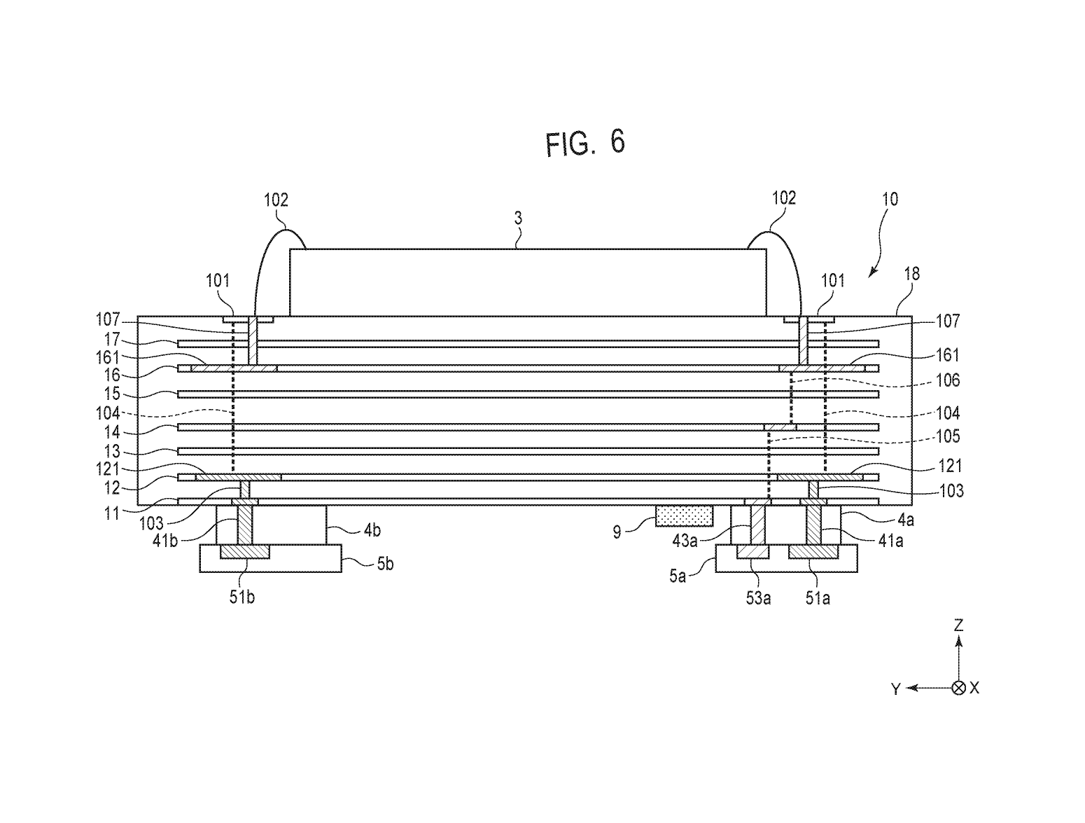

FIG. 6 is a cross-sectional view of the wiring board 10 according to the present embodiment, and is a cross-sectional view of the wiring board 10 taken along line A-A’ of FIG. 4. As illustrated in FIG. 6, the wiring board 10 is a multilayer substrate having a plurality of wiring layers 11 to 18 formed on an insulating substrate. Although eight wiring layers 11 to 18 are illustrated in FIG. 6, the number of wiring layers is not limited thereto.

The wiring layer 11 is formed on the lower surface of the wiring board 10, and the wiring layer 11 is provided with the connection portions 4a and 4b and a circuit component 9. The connection portions 4a, 4b may be, for example, a connector component. The connection portion (first connector component) 4a includes conductive leads 41a and 43a provided in a resin base material. One end of the lead 41a is connected to the digital power wiring 51a of the flexible wiring unit 5a, and the other end of the lead 41a is connected to the digital power wiring pattern of the wiring layer 11. One end of the lead 43a is connected to the analog power wiring 53a of the flexible wiring unit 5a, and the other end of the lead 43a is connected to the analog power wiring pattern of the wiring layer 11. Although not illustrated in FIG. 6, the connection portion 4a further includes two leads connected to the ground wirings 52a and 54a of the flexible wiring unit 5a, and these leads are connected to different ground patterns of the wiring layer 11. The connection portion (second connector component) 4b similarly includes a lead 41b, and the lead 41b connects the digital power wiring 51b and the digital power wiring pattern of the wiring layer 11. Although not illustrated in FIG. 6, the connection portion 4b connects the ground wiring 52b of the flexible wiring unit 5b and the ground pattern of the wiring layer 11. The connection portions 4a and 4b may be joint members such as solder separated from each other. The circuit component 9 may be, for example, a capacitor or a linear regulator.

The wiring layer 12 is provided above the wiring layer 11. The wiring layer 12 includes a digital power wiring pattern (first power wiring pattern) 121. The digital power wiring pattern 121 of the wiring layer 12 has the largest area among the plurality of digital power wiring patterns constituting the digital power wiring (first power wiring) provided on the wiring board 10. Therefore, the digital power wiring pattern 121 may radiate the largest noise among the plurality of digital power wiring patterns. The digital power wiring pattern 121 of the wiring layer 12 is connected to the digital power wiring pattern of the wiring layer 11 through the via 103. The digital power wiring pattern 121 is connected to the pad 101 through the via 104.

The wiring layer 13 is provided above the wiring layer 12. The wiring layer 13 is provided with, for example, a ground wiring pattern. The ground wiring pattern may be connected to the ground wiring pattern of other wiring layers, the pad 101, the connection portions 4a and 4b, and the like through vias (not illustrated).

The wiring layer 14 is provided above the wiring layer 13. The wiring layer 14 is provided with an analog power wiring pattern. The analog power wiring pattern of the wiring layer 14 is connected to the analog power wiring pattern of the wiring layer 11 via the via 105. The wiring layer 15 is provided above the wiring layer 14. The wiring layer 15 is provided with, for example, a power wiring pattern. Note that the wiring layer 14 may include a signal wiring pattern.

The wiring layer 16 is provided above the wiring layer 15. The wiring layer 16 includes an analog power wiring pattern (second power wiring pattern) 161. The analog power wiring pattern 161 of the wiring layer 16 has the largest area among the plurality of analog power wiring patterns constituting the analog power wiring (second power wiring) provided on the wiring board 10. Therefore, the analog power wiring pattern 161 is most strongly affected by noise from the digital power wiring pattern among the plurality of analog power wiring patterns 161. The analog power wiring pattern 161 of the wiring layer 16 is connected to the analog power wiring pattern of the wiring layer 14 via the via 106. The analog power wiring pattern 161 is connected to the pad 101 through the via 107.

The wiring layer 17 is provided above the wiring layer 16. The wiring layer 17 is provided with a ground wiring pattern. For example, the ground wiring pattern may be formed on substantially the entire wiring layer 17. By providing the ground wiring pattern having a large area, it is possible to reduce the impedance of the ground wiring pattern and shield noise generated in other wiring layers. The ground wiring pattern may be connected to the ground wiring pattern of other wiring layers, the pad 101, the connection portions 4a and 4b, and the like through vias (not illustrated).

The wiring layer 18 is provided above the wiring layer 17 and on the upper surface of the wiring board 10. A plurality of pads 101 are formed in the wiring layer 18. As described above, the plurality of pads 101 may include the pads 101 connected to the digital power wiring pattern 121, the pads 101 connected to the analog power wiring pattern 161, the pads 101 connected to the ground wiring pattern, and the pads 101 connected to the signal wiring pattern. The pad 101 is connected to the analog circuit 32 and the digital circuit 33 in the semiconductor element 3 via a bonding wire 102. The analog circuit 32 and the digital circuit 33 may be connected to a common ground wiring pattern of the wiring board 10, or may be connected to different ground wiring patterns of the wiring layers 13 and 17. By connecting the analog circuit 32 and the digital circuit 33 to the ground pattern having a large area, it is possible to reduce potential fluctuation due to noise of the ground wiring pattern.

In FIG. 6, power is supplied to the analog power wiring pattern 161 via the flexible wiring unit 5b and the connection portion 4b, but the present disclosure is not limited thereto. For example, power may be supplied to the analog power wiring pattern 161 via a linear regulator included in the circuit component 9. By performing the step-down process by the linear regulator of the circuit component 9, the low noise voltage can be supplied to the analog power wiring pattern 161.

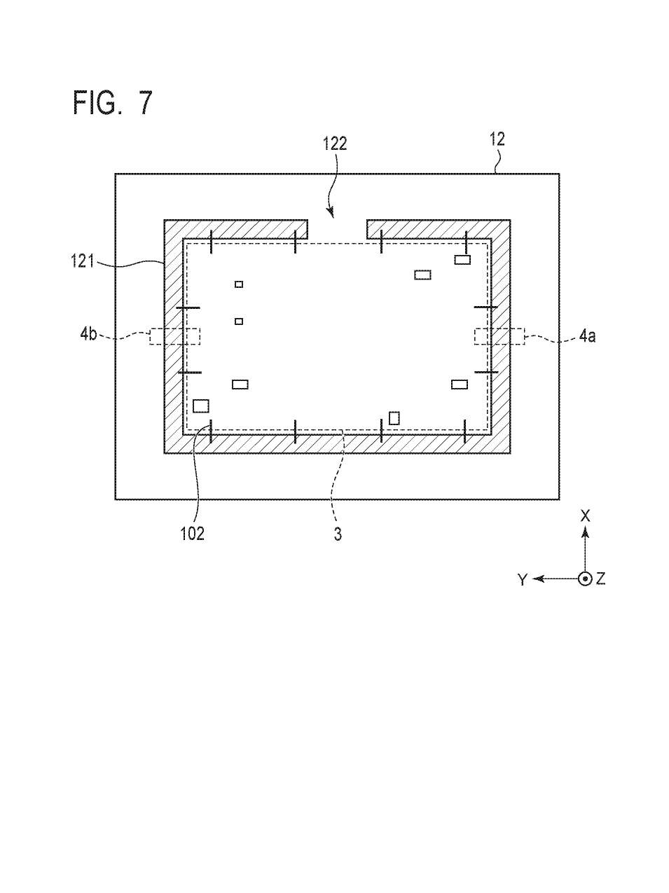

FIG. 7 is a plan view of the wiring layer 12 according to the present embodiment. The digital power wiring pattern 121 has a predetermined width and is bent to form a quadrilateral having longer sides and shorter sides. The digital power wiring pattern 121 does not overlap the semiconductor element 3 in a plan view. Thus, noise propagating from the digital power wiring pattern 121 to the semiconductor element 3 can be reduced. Although one digital power wiring pattern 121 is illustrated in FIG. 7, the digital power wiring pattern 121 may be divided into a plurality of patterns. Further, in FIG. 7, a part of the connection portions 4a and 4b is disposed so as to overlap the semiconductor element 3 in the direction perpendicular to the main surface of the semiconductor element 3, but at least one of the connection portions 4a and 4b may be disposed so as not to overlap the semiconductor element 3 in the direction perpendicular to the main surface of the semiconductor element 3. Furthermore, in the direction perpendicular to the main surface of the semiconductor element 3, the distance between the connection portion 4a and the connection portion 4b may be larger than the length of at least one side of the quadrilateral of the semiconductor element 3.

The digital power wiring pattern 121 is disposed so as to overlap the plurality of pads 101 in a plan view. As a result, the wiring path of the digital power wiring can be shortened, and low impedance and stable operation of the digital circuit 33 can be realized. In a region of the wiring layer 12 surrounded by the digital power wiring pattern 121, other power wiring patterns, signal wiring patterns, ground wiring patterns, lands, and the like are provided. Note that, the digital power wiring pattern 121 may be disposed outside the pads 101 in a plan view.

In a plan view of the wiring layer 12, the connection portions 4a and 4b are disposed so as to respectively overlap the centers of two opposing sides, for example, two shorter sides, of the digital power wiring pattern 121. The bonding wire 102 is connected to the digital power wiring pattern 121 through the pad 101 and the via 104. Although FIG. 7 illustrates twelve bonding wires 102, the number of bonding wires 102 is not limited to that illustrated in FIG. 7.

In the digital power wiring pattern 121, a gap 122 is provided at the center of one longer side of the digital power wiring pattern 121. The gap 122 forms an end of the digital power wiring pattern 121. As a result, a closed loop is prevented from being formed in the digital power wiring pattern 121, and the occurrence of potential fluctuation due to the induced magnetic field in the digital power wiring pattern 121 is suppressed. Note that the gap 122 may not necessarily be provided in the digital power wiring pattern 121.

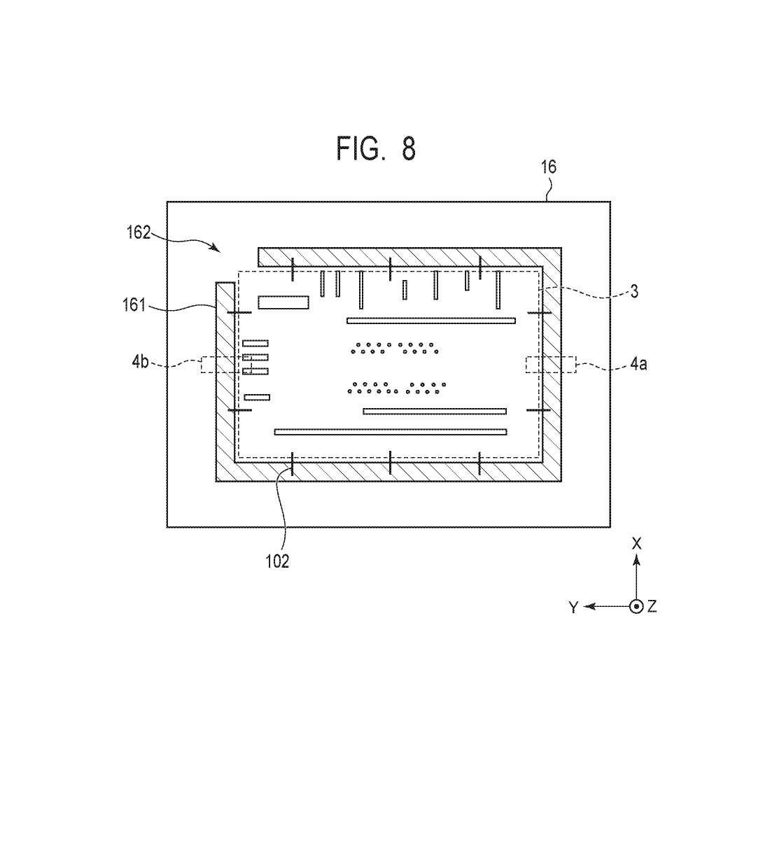

FIG. 8 is a plan view of the wiring layer 16 according to the present embodiment. The analog power wiring pattern 161 has a quadrilateral shape having a longer side and a shorter side similarly to the digital power wiring pattern 121 in a plan view. In a plan view, the analog power wiring pattern 161 overlaps the digital power wiring pattern 121. In a plan view, the analog power wiring pattern 161 does not overlap the semiconductor element 3. Thus, noise propagating from the analog power wiring pattern 161 to the semiconductor element 3 can be reduced. Although one analog power wiring pattern 161 is illustrated in FIG. 8, the analog power wiring pattern 161 may be divided into a plurality of patterns.

The analog power wiring pattern 161 is disposed so as to overlap the plurality of pads 101 in a plan view. As a result, the wiring path of the analog power wiring can be shortened, and low impedance and stable operation of the analog circuit 32 can be realized. In a region of the wiring layer 16 surrounded by the analog power wiring pattern 161, other power wiring patterns, signal wiring patterns, ground wiring patterns, lands, and the like are provided. The analog power wiring pattern 161 may be disposed outside the pads 101 in a plan view.

In a plan view of the wiring layer 16, the connection portions 4a and 4b are disposed so as to respectively overlap the midpoints of the two shorter sides of the analog power wiring pattern 161. The bonding wire 102 is connected to the analog power wiring pattern 161 via the pad 101 and the via 107. Although FIG. 8 illustrates ten bonding wires 102, the number of bonding wires 102 is not limited to that illustrated in FIG. 8.

A gap 162 is provided at one corner of the quadrilateral analog power wiring pattern 161. In a plan view, the gap 122 and the gap 162 may not overlap with each other. That is, the digital power wiring pattern 121 may have a portion that does not overlap the analog power wiring pattern 161 and the analog power wiring pattern 161 may have a portion that does not overlap the digital power wiring pattern 121 in a plan view (in the stacking direction of the multilayer substrate).

As described above, the amount of current flowing from the digital power wiring pattern 121 to the digital circuit 33 increases and the noise generated in the digital circuit 33 increases due to the improvement of the processing capability associated with the high functionality of the digital circuit 33. For example, the amount of current supplied to the digital circuit 33 increases with an increase in the number of pixels or an increase in the signal transfer rate. Since a large amount of current flows through the digital power wiring pattern 121, noise radiated from the digital power wiring pattern 121 may increase. When the potential of the analog power wiring pattern 161 fluctuates, the output of the analog circuit 32 changes. For example, when the potential fluctuation of the analog power wiring pattern 161 supplying power to the pixels 31 of the analog circuit 32 is large, disturbance may occur in an image generated by the semiconductor element 3. Further, since the digital power wiring pattern 121 overlaps the analog power wiring pattern 161, the current generated in the digital power wiring pattern 121 by the operation of the digital circuit 33 generates an induced current in the analog power wiring pattern 161. As a result, the operation of the analog circuit 32 becomes unstable due to the potential fluctuation generated in the analog power wiring pattern 161, and a disturbance such as a streak occurs in the image generated by the plurality of pixels 31. According to the present embodiment, as described in detail below, it is possible to reduce noise in the analog power wiring pattern 161 by lowering the maximum value of the current of the digital power wiring pattern 121.

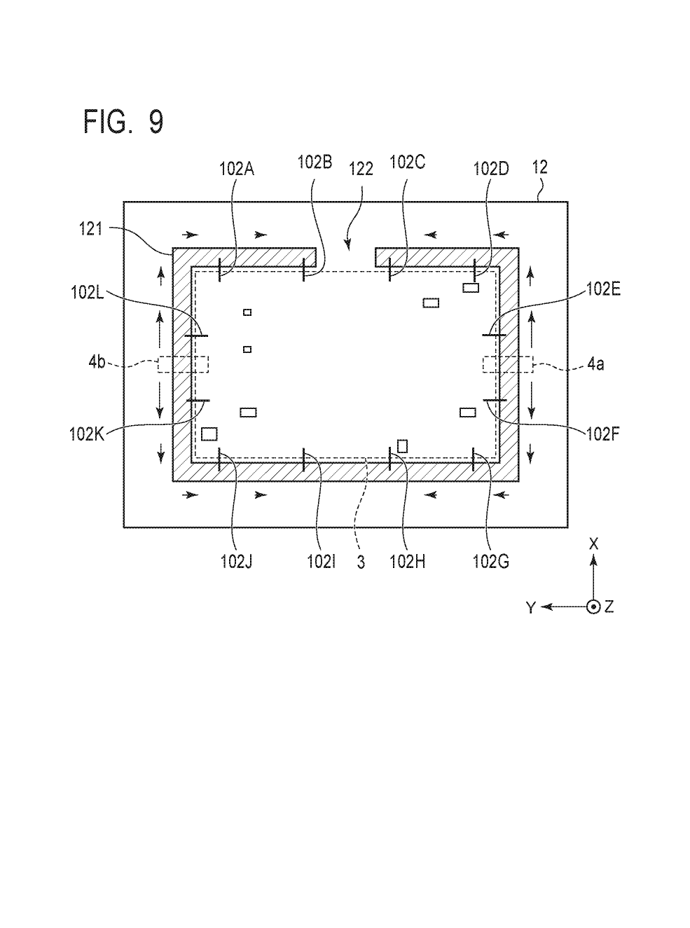

FIG. 9 is a schematic diagram illustrating a current of the digital power wiring pattern 121 according to the present embodiment. In a plan view, two connection portions 4a and 4b are disposed in the digital power wiring pattern 121. Twelve bonding wires 102A to 102L are connected to the digital power wiring pattern 121. In a plan view, when two longer sides among four sides of the quadrilateral of the main surface of the semiconductor element 3 are defined as a first side and a third side, respectively, and two shorter sides among four sides of the quadrilateral of the main surface of the semiconductor element 3 are defined as a second side and a fourth side, respectively, the bonding wires 102A to 102D face the first side, the bonding wires 102E and 102F face the fourth side, the bonding wires 102G to 102J face the third side, and the bonding wires 102K and 102L face the second side. Arrows in FIG. 9 indicate currents supplied from the connection portions 4a and 4b, respectively. The length of the arrow indicates the magnitude of the current value, and the longer the arrow is, the larger the current value is. It is assumed that the current values of the bonding wires 102A to 102L are equal to each other.

Since the current flowing through the digital power wiring pattern 121 is added toward the connection portions 4a and 4b, a larger current flows toward the connection portions 4a and 4b. Three bonding wires, a connection portion 4a, six bonding wires, a connection portion 4b, and three bonding wires are connected to the digital power wiring pattern 121 in the clockwise direction starting from the gap 122. Since a current corresponding to three bonding wires flows in the vicinity of the connection portions 4a and 4b, the maximum value of the current flowing through the digital power wiring pattern 121 becomes a current value corresponding to three bonding wires. As described above, by providing the plurality of connection portions 4a and 4b, the maximum value of the current of the digital power wiring pattern 121 can be lowered. Therefore, it is possible to reduce the potential fluctuation of the analog power wiring pattern 161 caused by the current change of the digital power wiring pattern 121 and to suppress the degradation of the image quality.

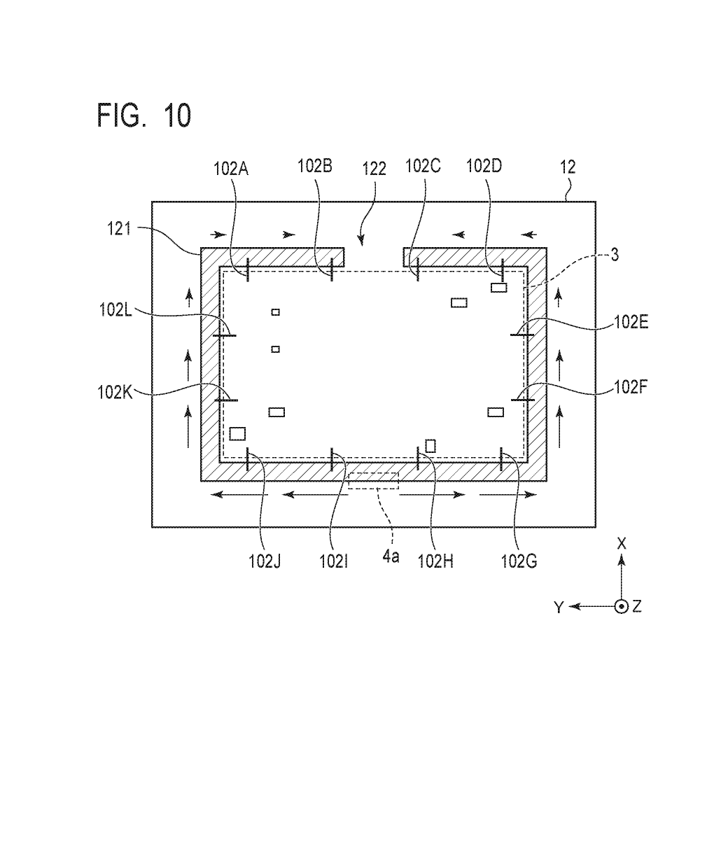

FIG. 10 is a schematic diagram illustrating a current of a digital power wiring pattern 121 according to a modified example. In a plan view, only one connection portion 4a is disposed in the digital power wiring pattern 121 in the modified example. The six bonding wires, the connection portion 4a, and the six bonding wires are connected to the digital power wiring pattern 121 in the clockwise direction starting from the gap 122. Since a current corresponding to six bonding wires flows in the vicinity of the connection portion 4a, the maximum value of the current of the digital power wiring pattern 121 becomes a current value corresponding to six bonding wires.

As described above, by providing the plurality of connection portions 4a and 4b, the maximum value of the current of the digital power wiring pattern 121 can be suppressed to half. As a result, the maximum value of the current induced in the analog power wiring pattern 161 overlapping the digital power wiring pattern 121 in a plan view can also be suppressed. According to the present embodiment, by lowering the maximum value of the current of the digital power wiring pattern 121, it is possible to reduce the potential fluctuation of the analog power wiring pattern 161 caused by the current change of the digital power wiring pattern 121. This makes it possible to suppress a decrease in image quality.

Note that although in FIG. 9, the current values of the bonding wires 102A to 102L are equal to each other, the present disclosure is not limited thereto. When the current values of the bonding wires 102A to 102L are different from each other, the connection portions 4a and 4b may be provided so that the total value of the currents of the bonding wires 102 connected to the connection portions 4a and 4b is substantially equal. Accordingly, the maximum value of the current in the digital power wiring pattern 121 can be effectively reduced.

As described above, in the present embodiment, by supplying power from the connection portion 4 to the digital power wiring pattern 121, the impedance of the power supply source can be lowered regardless of the frequency band, and an electronic equipment that operates well can be provided.

Further, in the present embodiment, the connection portion 4 is disposed on the wiring path connecting the two bonding wires 102, and at least one bonding wire 102 is disposed on the wiring path connecting the two connection portions 4 in the digital power wiring pattern 121. Accordingly, the maximum value of the current of the digital power wiring pattern 121 can be lowered, and the operation of the electronic equipment can be further improved.

Here, it is assumed that the number of bonding wires 102 is M, the number of connection portions 4 is N, and a natural number obtained by rounding down the value of M/(2N) with cutting off the value below the decimal point is denoted as X. Note that M and N are each a natural number of 2 or more. In the case where the gap 122 that forms the end portion of the digital power wiring pattern 121 is provided, 2 × X or (2 × X + 1) bonding wires 102 may be provided from each arbitrary end portion to the connection portion 4 closest to the arbitrary end portion. With such an arrangement, the maximum value of the current of the digital power wiring pattern 121 can be lowered.

### Second Embodiment

Next, an electronic equipment according to a second embodiment will be described. In the electronic equipment according to the present embodiment, the positions of the connection portions 4a and 4b are different from those of the first embodiment. Hereinafter, a configuration different from that of the first embodiment will be mainly described.

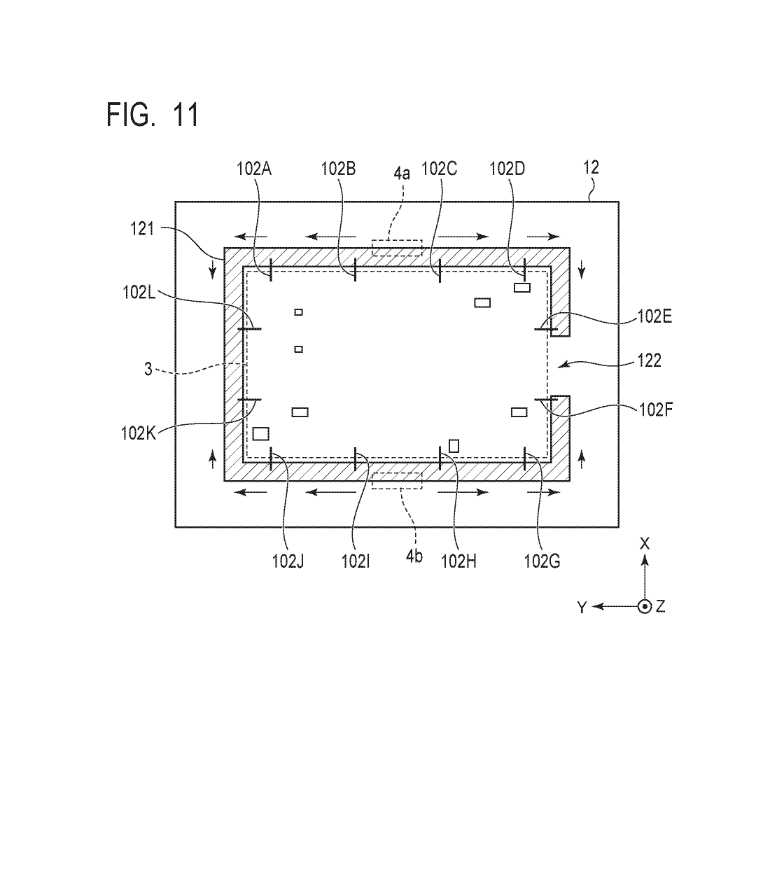

FIG. 11 is a plan view of the wiring layer 12 according to the present embodiment. The connection portions 4a and 4b are disposed so as to respectively overlap the centers of the two longer sides of the digital power wiring pattern 121. A gap 122 is provided at the center of one shorter side of the digital power wiring pattern 121.

Also in the present embodiment, since the power is supplied from the connection portion 4 to the digital power wiring pattern 121, it is possible to provide an electronic equipment that can reduce noise regardless of the frequency band and operate well. When the connection portions 4a and 4b are disposed so as to overlap the two longer sides of the digital power wiring pattern 121 in a plan view, the configuration of the present embodiment may be effective.

### Third Embodiment

Next, an electronic equipment according to a third embodiment will be described. The electronic equipment according to the present embodiment differs from the first embodiment in the position of the gap 122. Hereinafter, a configuration different from that of the first embodiment will be mainly described.

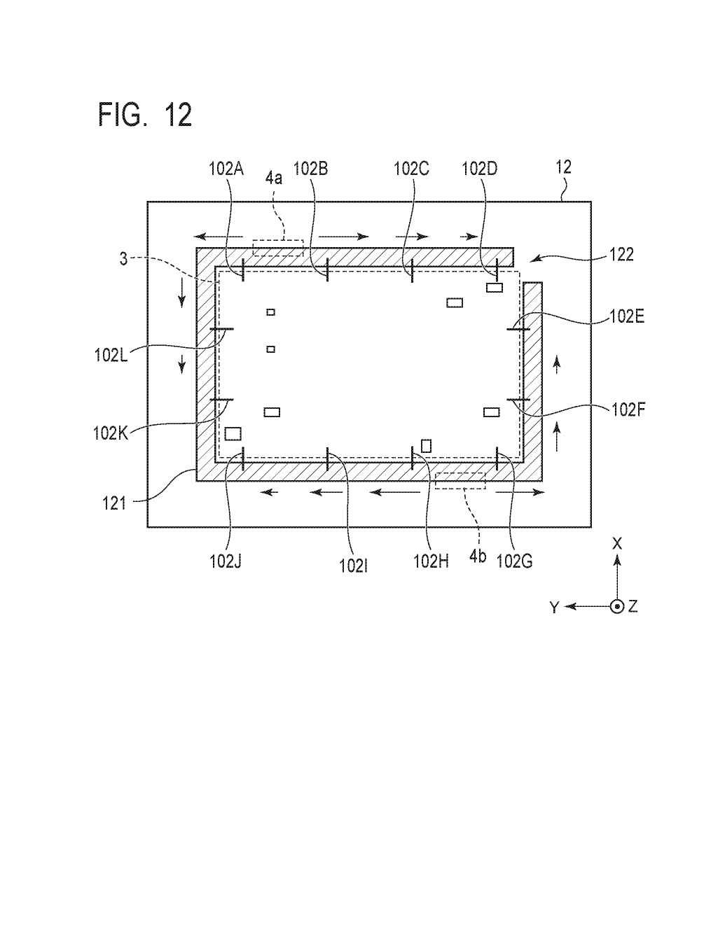

FIG. 12 is a plan view of the wiring layer 12 according to the present embodiment. A gap 122 is provided at one corner of the quadrilateral digital power wiring pattern 121. The connection portions 4a and 4b are disposed so as to be offset by a predetermined distance from the center of the two opposing longer sides of the digital power wiring pattern 121.

Also in the present embodiment, since power is supplied from the connection portion 4 to the digital power wiring pattern 121, it is possible to reduce noise regardless of the frequency band and provide an electronic equipment that operates well.

### Fourth Embodiment

Next, an electronic equipment according to a fourth embodiment will be described. The electronic equipment according to the present embodiment is different from the first embodiment in that three connection portions 4a to 4c are provided. Hereinafter, a configuration different from that of the first embodiment will be mainly described.

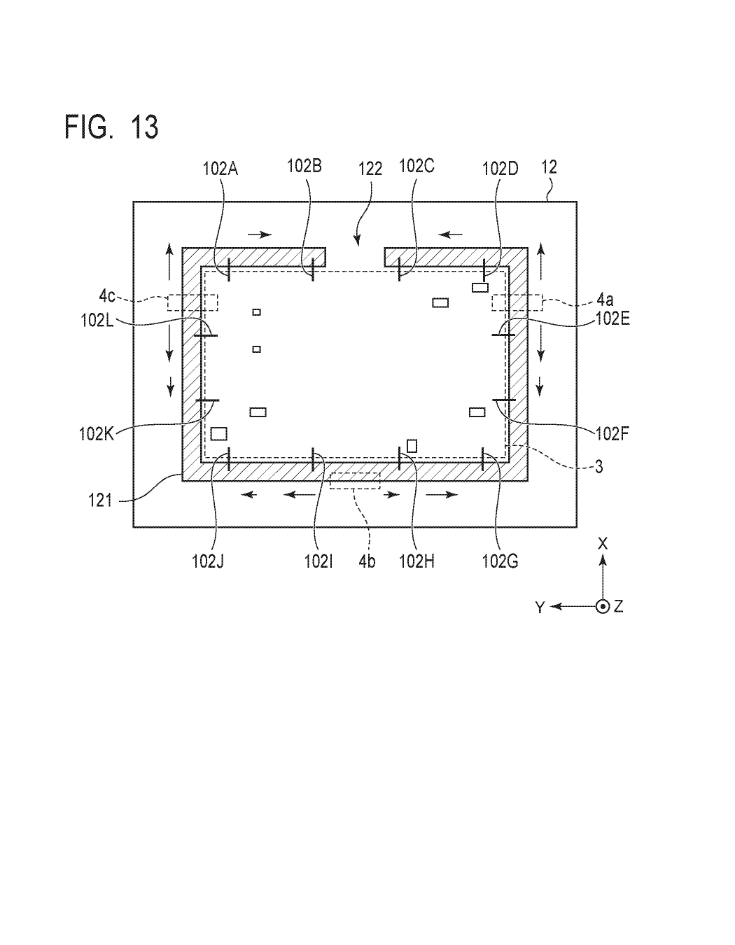

FIG. 13 is a plan view of the wiring layer 12 according to the present embodiment. A gap 122 is formed at the center of one longer side of the digital power wiring pattern 121, and a connection portion 4b is provided at the center of the other longer side. The connection portions 4a and 4b are provided at positions offset by a predetermined distance from the centers of the two shorter sides of the digital power wiring pattern 121 facing each other. In a plan view of the wiring layer 12, the connection portions 4a to 4c overlap the digital power wiring pattern 121. Two bonding wires, the connection portion 4a, four bonding wires, the connection portion 4b, four bonding wires, the connection portion 4c, and two bonding wires are connected to the digital power wiring pattern 121 clockwise starting from the gap 122. Since a current corresponding to two bonding wires flows in the vicinity of the connection portions 4a to 4c, the maximum value of the current of the digital power wiring pattern 121 becomes a current value corresponding to two bonding wires.

Also in the present embodiment, since power is supplied from the connection portion 4 to the digital power wiring pattern 121, it is possible to reduce noise regardless of the frequency band and provide an electronic equipment that operates well. In particular, in the present embodiment, as the number of connection portions increases, the maximum value of the current can be reduced, and the operation of the electronic equipment can be further improved.

### Fifth Embodiment

Next, an electronic equipment according to a fifth embodiment will be described. The electronic equipment according to the present embodiment is different from the first embodiment in that two gaps 122 are provided. Hereinafter, a configuration different from that of the first embodiment will be mainly described.

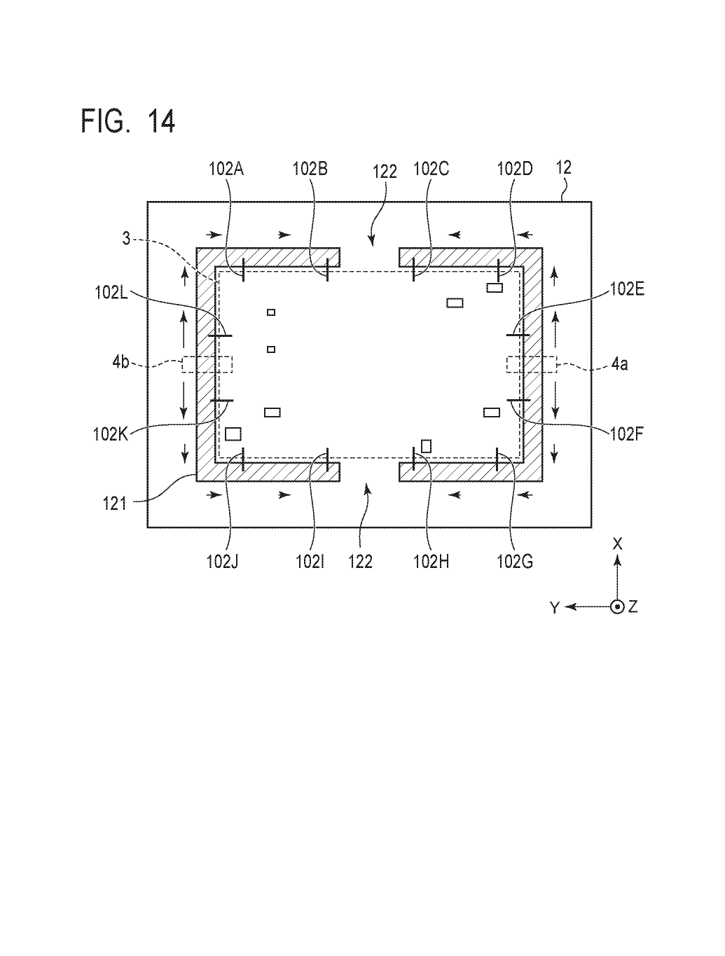

FIG. 14 is a plan view of the wiring layer 12 according to the present embodiment. The positions of the connection portions 4a and 4b are the same as in the second embodiment. The gap 122 is provided at the center of the two longer sides of the digital power wiring pattern 121, and the digital power wiring pattern 121 is divided by the two gaps 122. Thus, the number of wiring paths between the two bonding wires 102 is different from that of the first embodiment. For example, in the first embodiment, the number of wiring paths between the bonding wire 102B (first conductive member) opposed to one longer side of the digital power wiring pattern 121 and the bonding wire 102E (fourth conductive member) opposed to one shorter side of the digital power wiring pattern 121 is one in the digital power wiring pattern 121 of the wiring layer 12 that constitutes the largest number of digital power wirings. On the other hand, in the digital power wiring pattern 121 of the present embodiment, the number of wiring paths between the bonding wire 102B and the bonding wire 102E is zero.

Also in the present embodiment, since power is supplied from the connection portion 4 to the digital power wiring pattern 121, it is possible to reduce noise regardless of the frequency band and provide an electronic equipment that operates well.

### Sixth Embodiment

Next, an electronic equipment according to a sixth embodiment will be described. The electronic equipment according to the present embodiment differs from the first embodiment in that it includes digital power wiring patterns 121a and 121b. Hereinafter, a configuration different from that of the first embodiment will be mainly described.

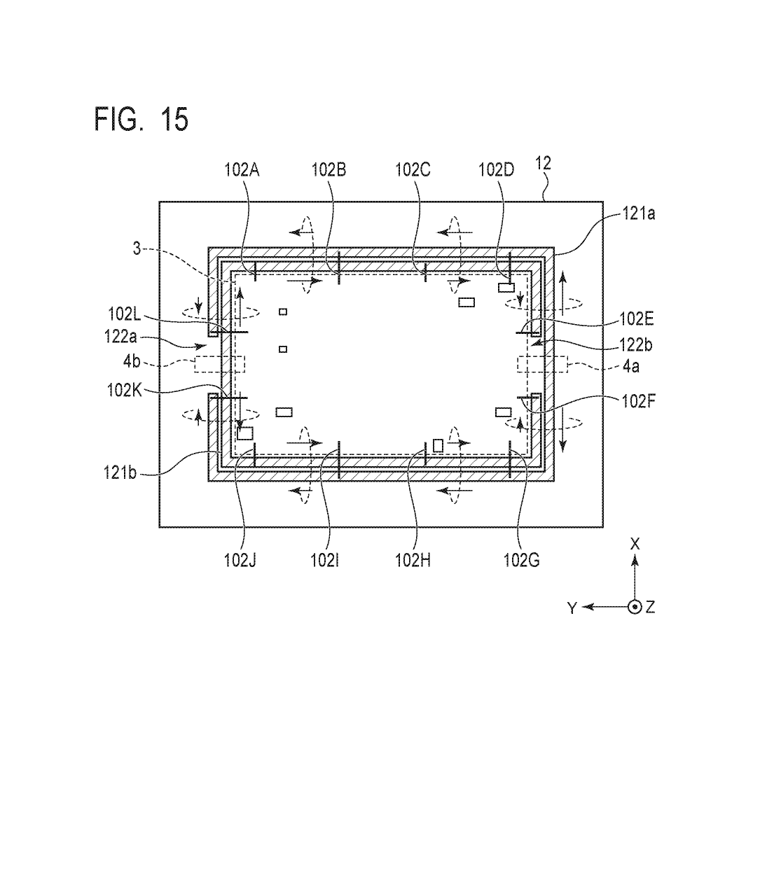

FIG. 15 is a plan view of the wiring layer 12 according to the present embodiment. The wiring layer 12 includes two digital power wiring patterns 121a and 121b. In a plan view, the digital power wiring patterns 121a and 121b have a quadrilateral shape, the digital power wiring pattern 121b is provided so as to surround the semiconductor element 3, and the digital power wiring pattern 121a is further provided so as to surround the digital power wiring pattern 121b. The manner in which the digital power wiring pattern 121a surrounds the digital power wiring pattern 121b is not limited to the example of FIG. 15. For example, when one of the four sides of each of the digital power wiring patterns 121a and 121b is not present, two opposing sides of the digital power wiring pattern 121b may be disposed between the two opposing sides of the digital power wiring pattern 121a. Further, only one of the sides of the digital power wiring pattern 121b may be disposed between two opposing sides of the digital power wiring pattern 121a. In any of the above arrangements, a portion (first portion and second portion) of each of the two opposing sides of the digital power wiring pattern 121a and a portion (third portion and fourth portion) of each of the two opposing sides of the digital power wiring pattern 121b may be positioned on the same straight line.

The digital power wiring patterns 121a and 121b have substantially the same width. The digital power wiring pattern (first wiring pattern) 121a has the largest area among the plurality of digital power wiring patterns of the plurality of layers connected to the connection portion 4a, and the digital power wiring pattern 121b (second wiring pattern) has the largest area among the plurality of digital power wiring patterns of the plurality of layers connected to the connection portion 4b. Similarly, the analog power wiring pattern (third wiring pattern) 161 has the largest area among the plurality of analog power wiring patterns of the plurality of layers.

The connection portion 4a is disposed so as to overlap the center of one shorter side of the digital power wiring pattern 121a. A gap 122a is provided at the center of the other shorter side of the digital power wiring pattern 121a. The connection portion 4b faces the connection portion 4a and is disposed so as to overlap the center of one shorter side of the digital power wiring pattern 121b. A gap 122b is provided at the center of the other shorter side of the digital power wiring pattern 121b so as to face the gap 122a. The digital power wiring patterns 121a and 121b may be supplied with power from both of the connection portions 4a and 4b.

In the digital power wiring pattern 121a, three bonding wires, the connection portion 4a, and three bonding wires are connected in a clockwise direction starting from the gap 122a. In the digital power wiring pattern 121b, three bonding wires, the connection portion 4b, and three bonding wires are connected in a clockwise direction starting from the gap 122b. The bonding wires 102 are alternately connected to the digital power wiring patterns 121a and 121b in the clockwise direction.

Also in the present embodiment, since power is supplied from the connection portion 4 to the digital power wiring pattern 121, it is possible to reduce noise regardless of the frequency band and provide an electronic equipment that operates well. In particular, in the present embodiment, since the digital power wiring patterns 121a and 121b are supplied with power from the connection portions 4a and 4b disposed at positions facing each other, currents in opposite directions flow through the digital power wiring patterns 121a and 121b. Therefore, the induced magnetic fields in the digital power wiring patterns 121a and 121b cancel each other out, noise from the digital power wiring pattern 121 to the analog power wiring pattern 161 is further effectively reduced, and the operation of the electronic equipment can be further improved.

### Seventh Embodiment

Next, an electronic equipment according to a seventh embodiment will be described. The electronic equipment according to the present embodiment is different from the electronic equipment according to the sixth embodiment in that two digital power wiring patterns are provided in different wiring layers 12 and 13. Hereinafter, a configuration different from that of the sixth embodiment will be mainly described.

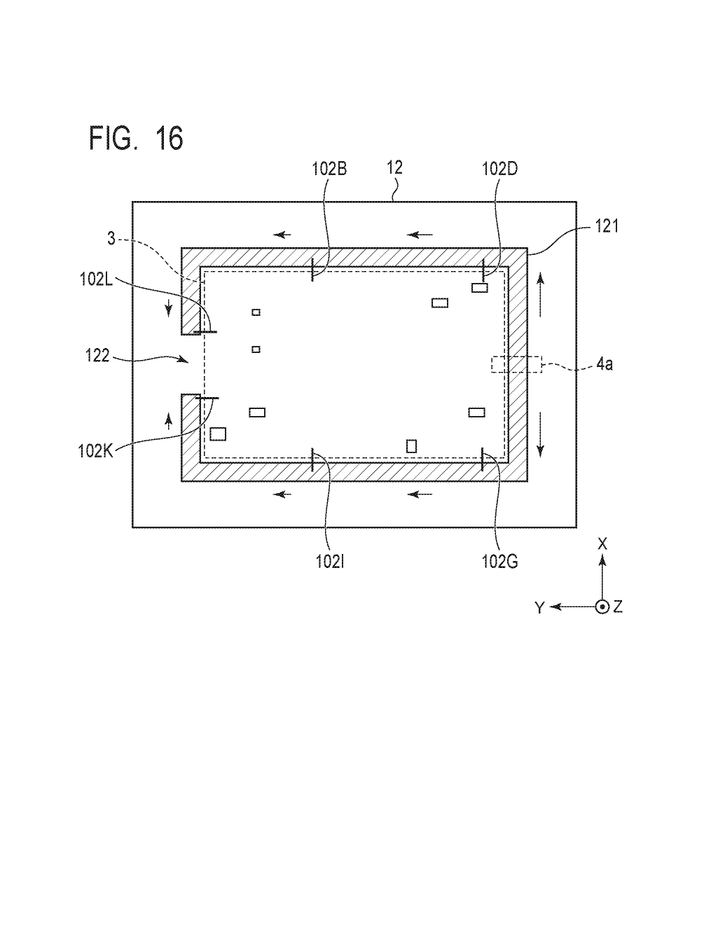

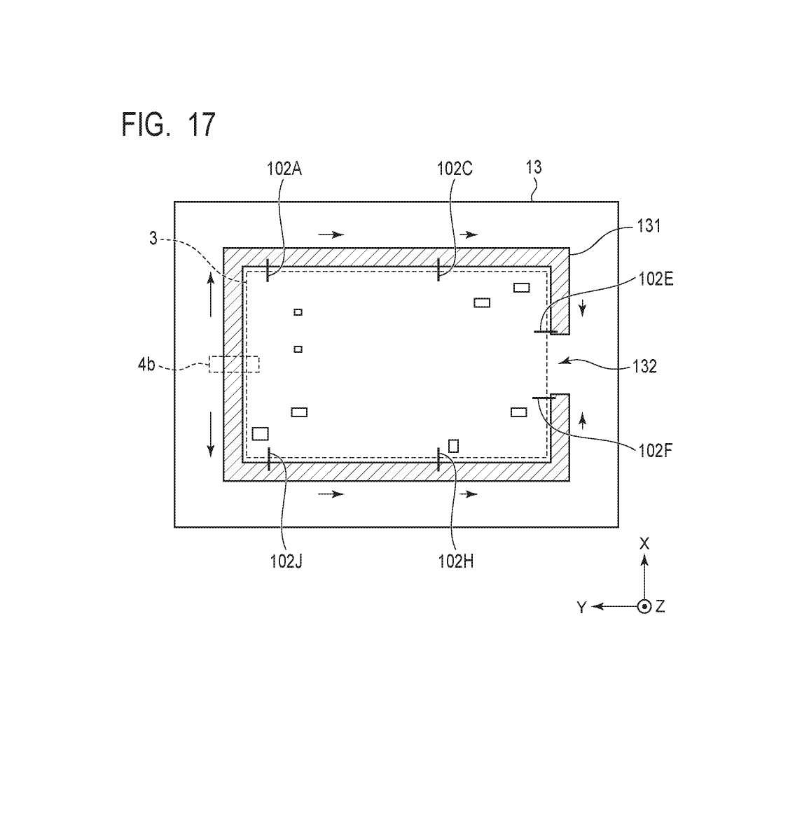

FIG. 16 is a plan view of the wiring layer 12 according to the present embodiment, and FIG. 17 is a plan view of the wiring layer 13 according to the present embodiment. The digital power wiring pattern 121 is formed in the wiring layer 12, and is configured in substantially the same manner as the digital power wiring pattern 121a of the sixth embodiment. Further, the digital power wiring pattern 131 is formed in the wiring layer 13, and is configured in substantially the same manner as the digital power wiring pattern 121b of the sixth embodiment. In a plan view, the digital power wiring patterns 121 and 131 overlap each other, but the gaps 122 and 132 and the connection portions 4a and 4b are provided at positions facing each other. The bonding wires 102 are alternately connected to the digital power wiring patterns 121 and 131 in the clockwise direction.

Also in the present embodiment, since power is supplied from the connection portion 4 to the digital power wiring pattern 121, it is possible to reduce noise regardless of the frequency band and provide an electronic equipment that operates well. Further, as in the sixth embodiment, currents in opposite directions flow through the digital power wiring patterns 121 and 131. Therefore, the induced magnetic fields from the digital power wiring patterns 121 and 131 are canceled out from each other, noise from the digital power wiring pattern 121 and the digital power wiring pattern 131 to the analog power wiring pattern 161 is effectively reduced, and the operation of the electronic equipment can be further improved.

Although the two digital power wiring patterns 121 and 131 are provided in the wiring layers 12 and 13, the present disclosure is not limited thereto. However, the two digital power wiring patterns 121 and 131 may be provided in two adjacent wiring layers. Accordingly, the induced magnetic fields of the digital power wiring patterns 121 and 131 can be more effectively canceled, and noise can be more effectively reduced.

### Modified Embodiment

The present disclosure is not limited to the above embodiment, and various modifications are possible within the technical idea of the present disclosure. In addition, the effects described in the embodiments merely enumerate the effects generated from the present disclosure, and the effects according to the present disclosure are not limited to those described in the embodiments.

The combination of the first circuit and the second circuit in which the power system to be supplied is divided is not limited to the case where the first circuit is a digital circuit and the second circuit is an analog circuit. For example, the first circuit may be an analog circuit, the second circuit may be a digital circuit. For example, the first circuit may be a first digital circuit, the second circuit may be a second digital circuit. For example, the first circuit may be a first analog circuit, and the second circuit may be a second analog circuit.

Although the above-described embodiment is applied to an electronic equipment such as an imaging apparatus, the present disclosure is not limited thereto. The modules described above are also applicable to mobile devices such as smartphones, tablet computers, laptop computers, and portable game machines, wearable devices, and the like. Further, the above-described module can be applied to an image forming apparatus, for example, a printer, a copier, a facsimile, and an electronic equipment such as a multifunction peripheral having these functions. In addition, the above-described module can be applied to communication equipment such as a modem and a router, medical equipment such as an X-ray imaging apparatus and an endoscope, industrial equipment such as a robot and a semiconductor manufacturing apparatus, transportation equipment such as a vehicle, an airplane, and a ship, and the like.

The disclosure of the present specification includes not only the matter explicitly described in the present specification but also all matters which can be grasped from the present specification and the drawings attached to the present specification. Also, the disclosure herein includes a complement of the individual concepts described herein. In other words, for example, when there is a description of “A is B” in this specification, it can be said that this specification discloses that “A is not B” even if a description of “A is not B” is omitted. This is because it is assumed that the case where “A is not B” is considered when “A is B” is described.

While the present disclosure has been described with reference to embodiments, it is to be understood that the present disclosure is not limited to the disclosed embodiments. The scope of the following claims is to be accorded the broadest interpretation so as to encompass all such modifications and equivalent structures and functions.

This application claims the benefit of Japanese Patent Application No. 2025-032060, filed February 28, 2025, which is hereby incorporated by reference herein in its entirety.

What is claimed is:

1. An electronic equipment comprising:
a semiconductor element including a first circuit and a second circuit;
a wiring board on which the semiconductor element is mounted;
a flexible wiring unit connected to the wiring board;
a power unit connected to the flexible wiring unit; and
a plurality of conductive members connecting the wiring board and the semiconductor element,
wherein the electronic equipment is configured to supply power from the power unit to the first circuit via the flexible wiring unit, a first power wiring provided on the wiring board, and at least four conductive members of the plurality of conductive members, and to supply power from the power unit to the second circuit via the flexible wiring unit, a second power wiring provided on the wiring board, and at least one conductive member of the plurality of conductive members,
wherein the four conductive members include a first conductive member, a second conductive member, a third conductive member, and a fourth conductive member,
wherein a first connection portion among a plurality of connection portions connecting the flexible wiring unit and the wiring board is disposed on a wiring path connecting the first conductive member and the second conductive member in the first power wiring, and
wherein a second connection portion among the plurality of connection portions connecting the flexible wiring unit and the wiring board is disposed on a wiring path connecting the third conductive member and the fourth conductive member in the first power wiring.

2. The electronic equipment according to claim 1, wherein at least one of the first connection portion and the second connection portion is disposed so as not to overlap the semiconductor element in a direction perpendicular to a main surface of the semiconductor element.

3. The electronic equipment according to claim 1,
wherein a main surface of the semiconductor element has a quadrilateral shape, and
wherein a distance between the first connection portion and the second connection portion is larger than a length of at least one of four sides of the quadrilateral.

4. The electronic equipment according to claim 1, wherein the second conductive member is disposed on a wiring path connecting the first connection portion and the second connection portion in the first power wiring.

5. The electronic equipment according to claim 1,
wherein the first circuit is a digital circuit, and
wherein the second circuit is an analog circuit.

6. The electronic equipment according to claim 1,
wherein a main surface of the semiconductor element has a quadrilateral shape,
wherein the first conductive member faces a first side of four sides of the quadrilateral,
wherein the second conductive member faces a second side of the four sides of the quadrilateral,
wherein the third conductive member faces a third side of the four sides of the quadrilateral, and
wherein the fourth conductive member faces a fourth side of the four sides of the quadrilateral.

7. The electronic equipment according to claim 6,
wherein a main surface of the semiconductor element has a quadrilateral shape, and
wherein two sides facing each other among the four sides are located between at least one of the first conductive member and the second conductive member and at least one of the third conductive member and the fourth conductive member.

8. The electronic equipment according to claim 1,
wherein the wiring board is a multilayer substrate, and
wherein among a plurality of wiring layers of the multilayer substrate, a first wiring layer constituting a largest number of the first power wirings is disposed so that a number of wiring paths between the first conductive member and the fourth conductive member in the first wiring layer is one or zero.

9. The electronic equipment according to claim 1,
wherein the wiring board is a multilayer substrate, and
wherein a wiring layer in which a first power wiring pattern having a largest area among a plurality of wiring patterns constituting the first power wiring is provided is different from a wiring layer in which a second power wiring pattern having a largest area among a plurality of wiring patterns constituting the second power wiring is provided.

10. The electronic equipment according to claim 9, wherein the first power wiring pattern overlaps the second power wiring pattern in a stacking direction of the multilayer substrate.

11. The electronic equipment according to claim 10, wherein the first power wiring pattern has a portion that does not overlap the second power wiring pattern in the stacking direction, the second power wiring pattern has a portion that does not overlap the first power wiring pattern in the stacking direction.

12. The electronic equipment according to claim 1, wherein when a number of the plurality of conductive members is M, a number of the plurality of connection portions is N, and a natural number obtained by rounding down a value obtained by dividing M by 2N with cutting off a value below a decimal point is X, the X or (X + 1) conductive members are provided between an arbitrary end portion of the first power wiring and the connection portion closest to the arbitrary end portion of the first power wiring among the N connection portions, 2 × X or (2 × X + 1) conductive members are provided between the N connection portions.

13. The electronic equipment according to claim 1, wherein the plurality of conductive members are bonding wires.

14. The electronic equipment according to claim 1,
wherein the first connection portion is configured by a first connector component, and
wherein the second connection portion is configured by a second connector component.

15. The electronic equipment according to claim 1, wherein the first connection portion and the second connection portion are formed of solder separated from each other.

16. The electronic equipment according to claim 1, wherein the first power wiring includes a first wiring pattern having a largest area among a plurality of wiring patterns connected to the first connection portion and a second wiring pattern having a largest area among a plurality of wiring patterns connected to the second connection portion, the second power wiring includes a third wiring pattern having a largest area among a plurality of wiring patterns connected to a third connection portion among a plurality of connection portions connecting the flexible wiring unit and the wiring board.

17. The electronic equipment according to claim 16, wherein in a plan view with respect to a main surface of the semiconductor element, a first portion and a second portion of the first wiring pattern and a third portion and a fourth portion of the second wiring pattern are positioned on a same straight line.

18. The electronic equipment according to claim 16, wherein a wiring layer in which the first wiring pattern is provided is provided between a wiring layer in which the third wiring pattern is provided and a wiring layer in which the second wiring pattern is provided.

19. The electronic equipment according to claim 1, wherein the semiconductor element is an imaging element.

20. The electronic equipment according to claim 1 further comprising a processing device configured to process a signal output from the semiconductor element and/or a storage device configured to store a signal output from the semiconductor device.
